(19) United States
(12) Patent Application Publication
(10) Pub. No.: US 2005/0266651 A1
(43) Pub. Date: Dec. 1, 2005

(54) Integrated via resistor

(75) Inventors: Richard F. Taylor, Campbell, CA (US); Hans T. Cramer, San Bruno, CA (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 10/857,671

(22) Filed: May 28, 2004

(51) Int. Cl. H01L 21/66

(52) U.S. Cl. 438/382

(57) ABSTRACT

A method of forming a resistor in an integrated circuit, comprising etching a first via in a first layer of dielectric material, depositing a layer of metal adjacent the first layer of dielectric material, depositing a second layer of dielectric material adjacent the layer of metal, and etching a second via in the second layer of dielectric material, said second via electrically connected in series to the first via by way of the layer of metal to form said resistor.

### BACKGROUND

Various circuit components are implemented into an integrated circuit (“IC”) using semiconductor integrated circuit processing technology. One such component is the resistor (e.g., a thin-film resistor). The resistor can be fashioned by an IC designer for a desired resistance value by manipulating physical properties of the resistor, such as the total area occupied by the resistor and the material composition of the resistor. However, in the context of IC processing, resistors have undesirably high tolerance values. For example, a 100 ohm resistor may have a tolerance of ±20 ohms. Thus, a designer intending to use a 100 ohm resistor in a particular IC may instead find that the resistor is closer to 120 ohms or 80 ohms. Such varying resistor values are typically attributed to unintentional variations in processing execution (“process variation”).

Because high tolerance values generally are considered unacceptable, IC designers often increase the total area of the resistor such that process variation no longer significantly impacts resistor values. For example, a first resistor with an intended surface area of 1 micron² may, due to process variation, result in a width that is 0.25 microns shorter than what was intended. This unintended loss of 0.25 microns in width results in a resistor value that may substantially differ from the desired resistor value. Conversely, a second resistor with a much larger area of 10 micron² that also loses the same 0.25 microns in width due to process variation is closer to the desired resistance value than the first resistor, because the loss of 0.25 microns impacts the second resistor to a lesser degree. However, while increasing resistor area decreases resistor tolerance values (i.e., “tightens” tolerance values), such an increase also precipitates an undesirable increase in the parasitic capacitance of the resistor to the substrate adjacent the IC.

### BRIEF SUMMARY

The problem noted above may be solved at least in part by a method of forming a resistor in an integrated circuit. One exemplary embodiment may comprise etching a first via in a first layer of dielectric material, depositing a layer of metal adjacent the first layer of dielectric material, depositing a second layer of dielectric material adjacent the layer of metal, and etching a second via in the second layer of dielectric material, said second via electrically connected in series to the first via by way of the layer of metal to form said resistor.

### BRIEF DESCRIPTION OF THE DRAWINGS

For a detailed description of exemplary embodiments of the invention, reference will now be made to the accompanying drawings in which:

FIG. 1 shows an IC comprising stacked vias in accordance with a preferred embodiment of the invention;

FIG. 2 shows a process implementing the embodiment of FIG. 1; and

FIG. 3 shows multiple unit cells arranged in series and parallel in accordance with embodiments of the invention.

### NOTATION AND NOMENCLATURE

Certain terms are used throughout the following description and claims to refer to particular system components. As one skilled in the art will appreciate, computer companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . . ” Also, the term “couple” or “couples” is intended to mean either an indirect or direct electrical connection. Thus, if a first device couples to a second device, that connection may be through a direct electrical connection, or through an indirect electrical connection via other devices and connections. Various numeric values are provided below, many of which merely to exemplify a preferred embodiment and should not be used to limit the scope of this disclosure. Also, all numeric values are approximate. Further, the term “adjacent” is generally meant to be interpreted as “abutting” and/or “immediately next to,” although in some embodiments, the term may be interpreted as “near” or “in close proximity to.” Thus, two adjacent items may abut one another or be separated by an intermediate item(s).

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

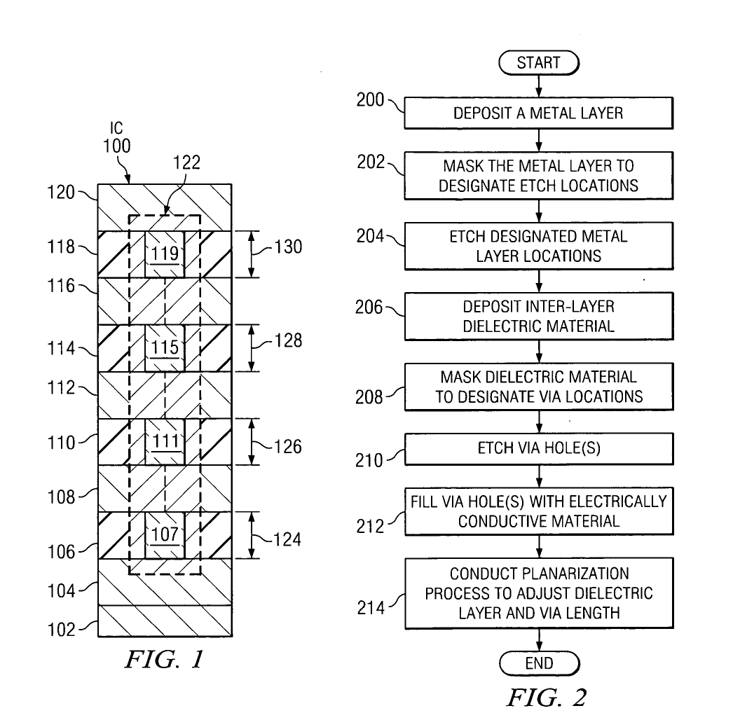

Described herein is a manufacturing process for implementing relatively tight tolerance, low parasitic capacitance electrical resistances by stacking vias in an IC. An IC implemented using such a process is illustrated in FIG. 1. More specifically, FIG. 1 shows an IC 100, or a portion thereof, comprising a substrate 102, a metal layer 104 stacked adjacent the substrate 102, a dielectric layer 106 stacked adjacent the metal layer 104, a metal layer 108 stacked adjacent the dielectric layer 106, and a dielectric layer 110 stacked adjacent the metal layer 108. The IC 100 further comprises a metal layer 112 stacked adjacent the dielectric layer 110, a dielectric layer 114 stacked adjacent the metal layer 112, a metal layer 116 stacked adjacent the dielectric layer 114, a dielectric layer 118 stacked adjacent the metal layer 116, and a metal layer 120 stacked adjacent the dielectric layer 118. Each of the dielectric layers 106, 110, 114, 118 comprises a via 107, 111, 115, 119, respectively. Other layers and materials may be included in the IC 100 without departing from the spirit of this disclosure.

Each of the vias 107, 111, 115, 119 has a resistance value. This resistance value depends on, among other things, the vertical length of the via, the cross-sectional area of the via, and the resistivity of the electrically conductive material inside the via (e.g., copper, tungsten). By electrically connecting multiple vias in series by way of the metal layers 108, 112, 116, an integrated via resistor 122 may be formed, wherein the resistance of the resistor 122 is approximately the sum of the resistances of the individual vias. For example, if each via has a resistance of approximately 5 ohms, then electrically connecting (i.e., “stacking”) the vias 107, 111 by way of the metal layer 108 produces the resistor 122 having an overall resistance value of about 10 ohms. Likewise, resistance values may be manipulated by placing vias in parallel. Although FIG. 1 shows the resistor 122 comprising all four vias 107, 111, 115, 119, any number and/or combination of vias may be used to form the resistor 122.

Each of the vias 107, 111, 115, 119 is in vertical alignment, as illustrated by the dashed lines, and is electrically connected with the other vias by way of the intervening metal layers. In the example above, because each via has a resistance of 5 ohms, the overall resistance produced by electrically connecting the four vias in series is approximately 20 ohms. Thus, the overall resistance present in the vias between the metal layer 104 and the metal layer 120 is 20 ohms. For instance, current may flow from the substrate 102, through the metal layer 104, the via 107, the metal layer 108, the via 111, the metal 112, the via 115, the metal layer 116, and finally the via 119 to reach the metal layer 120. By flowing through such a pathway, the current encounters the approximately 5-ohm resistance presented by each of the individual vias, for a total encountered resistance of about 20 ohms.

The only capacitance that is parasitic to the substrate 102 is that introduced by the bottom surface of the metal layer 104, which is a relatively small area. In this way, stacking multiple vias in series substantially reduces parasitic capacitance to the substrate 102 in comparison with commonly-used IC resistors. Furthermore, because the resistance of each via has a tolerance that is independent of the tolerance of the other vias, the overall resistance value of the resistor 122 produced by electrically connecting the vias in series is normalized and has a tighter tolerance than that associated with commonly-used IC resistors.

FIG. 2 illustrates the manufacturing process used to implement the resistor 122 of FIG. 1. The process may begin with the deposition of the metal layer 104 on the substrate 102 (block 200). The metal layer 104 may be masked to designate which areas of the metal layer 104 are to be etched during an etching process (block 202). The metal layer 104 subsequently is etched to remove areas of the metal layer 104 unprotected by the mask (block 204), and the mask is removed. The inter-layer dielectric 106 then is deposited adjacent the metal layer 104 (block 206). The dielectric layer 106 is masked to designate an area of the dielectric layer 106 that is to contain the via 107 (block 208). The dielectric layer 106 is etched, thereby creating the via 107 (block 210), and the mask is removed. The via 107 then is filled with an electrically conductive material, such as tungsten or copper (block 212). The dielectric layer 106 undergoes a planarization process, whereby the height of the dielectric layer is adjusted (block 214). This iterative manufacturing process then is repeated until the metal layers 108, 112, 116, 120, the dielectric layers 110, 114, 118 and the vias 111, 115, 119 are implemented as shown in FIG. 1.

The heights 124, 126, 128, 130 of the dielectric layers 106, 110, 114, 118, respectively, dictate the length of the via in that layer and thus the resistance of that via. The mask applied on each dielectric layer prior to etching the via in the layer dictates the cross-sectional area of the via, and thus the resistance of that via. The resistance of each via also is dictated by the resistivity of the material used to fill the via. In these ways, the resistance of each via may be manipulated as desired. The resistance value of the resistor 122 obtained by electrically connecting vias in series may be modified by adjusting the resistance of each individual via in the series or by altering the number of vias connected in the series.

As previously mentioned, resistances may be formed in an IC by arranging vias in series, parallel, or a combination thereof. While electrically connecting vias in series as shown in FIG. 1 decreases parasitic capacitance to the substrate 102 and tightens resistor tolerance, resistor tolerance is further improved (e.g., within 5%) by arranging vias in series and parallel. Series and/or parallel stacked via combinations may be implemented in any of a variety of ways, each of which is encompassed in the scope of this disclosure.

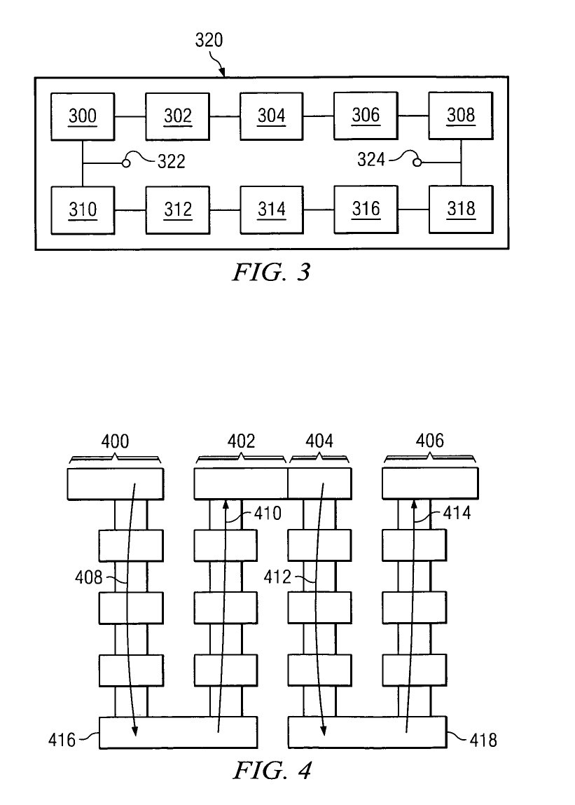

As previously discussed, the metal/dielectric stack of FIG. 1 comprises a stack of vias with a total resistance of, per the example provided above, about 20 ohms. This metal/dielectric stack may be referred to as a “unit cell,” wherein each unit cell has a resistance of 20 ohms. Multiple unit cells may be arranged in series and/or parallel on a substrate as desired to achieve specific resistance values in an IC. For example, a resistance of 50 ohms may be achieved by arranging multiple unit cells in series and parallel as shown in FIG. 3. More specifically, FIG. 3 comprises a top view of unit cells 300-318 arranged in series and parallel on the substrate 320. The unit cells 300-308 are arranged in series. Because each unit cell has a stacked via resistance of 20 ohms, the five unit cells 300-308 arranged in series have a total resistance of 100 ohms. Similarly, the five unit cells 310-318 arranged in series have a total resistance of 100 ohms. The 100-ohm series comprising the unit cells 300-308 is arranged in parallel with the 100-ohm series comprising the unit cells 310-318, thus producing an overall resistance of 50 ohms. The leads 322, 324 are shown simply to highlight the parallel interconnection between the aforementioned two 100-ohm series and may be coupled within the substrate per design specifications. The scope of this disclosure is not limited to unit cells of 20 ohms or series-parallel unit cell arrangements of 50 ohms but instead encompasses all possible arrangements of unit cells having any of a variety of resistance values. For example, two series of five-unit-cells each may be electrically connected in parallel, four series of 10-unit-cells each may be electrically connected in parallel, eight series of 20-unit-cells each may be electrically connected in parallel, 16 series of 40-unit-cells each may be electrically connected in parallel (with a possible tolerance of less than ±1%), 32 series of 80-unit-cells each may be electrically connected in parallel (also with a possible tolerance of less than ±1%), and so on.

Yet another embodiment is illustrated in FIG. 4, which shows a cross-sectional view of four unit cells electrically connected in series. Specifically, a unit cell 400 of 20 ohms is connected in series to a unit cell 402, also with a resistance of 20 ohms, by way of an electrically conductive plate 416. Thus, the series combination of the unit cell 400 and the unit cell 402 produces a total resistance of 40 ohms. Similarly, unit cells 404 and 406 are electrically connected in series by way of an electrically conductive plate 418, producing a total resistance of 40 ohms. Thus, a series combination of unit cells 404 and 406 with the unit cells 400 and 402 produces a series of unit cells with a total resistance of 80 ohms. In some instances, current may flow as indicated by arrows 408-414. As noted above, FIG. 4 simply illustrates an exemplary embodiment of the subject matter described herein and does not limit the scope of disclosure.

Many applications, such as precision analog and radio-frequency (“RF”) applications, are sensitive to the high resistor tolerances and substrate parasitic capacitance introduced by commonly-used IC resistors. Because the manufacturing process described herein produces stacked-via resistors with relatively low substrate parasitic capacitance and relatively tight tolerances, the process may be useful in, among other things, such precision analog and RF applications.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

1. A method of forming a resistor in an integrated circuit, comprising:
etching a first via in a first layer of dielectric material;
depositing a layer of metal adjacent the first layer of dielectric material;
depositing a second layer of dielectric material adjacent the layer of metal; and
etching a second via in the second layer of dielectric material, said second via electrically connected in series to the first via by way of the layer of metal to form said resistor.

2. The method of claim 1, further comprising conducting a planarization process to adjust the length of the first or second via.

3. The method of claim 1, wherein etching the first and second vias comprises filling each via with an electrically conductive material selected from a group consisting of tungsten and copper.

4. The method of claim 1, wherein etching the first and second vias comprises using a mask to dictate the cross-sectional area of each via.

5. The method of claim 1, further comprising repeating the acts of etching a first via, depositing a layer of metal, depositing a second layer of dielectric material and etching a second via until said resistor has a pre-determined resistance value.

6. An integrated circuit, comprising:
a first layer of dielectric material comprising a first via;
a layer of metal adjacent the layer of dielectric material; and
a second layer of dielectric material adjacent the layer of metal, said second layer comprising a second via;
wherein the first via and the second via are electrically connected in series to form a resistor.

7. The circuit of claim 6, wherein the vias are filled with an electrically conductive material selected from a group comprising tungsten and copper.

8. The circuit of claim 6, further comprising multiple vias electrically connected in series to the first and second vias to achieve a pre-determined resistance value.

9. The circuit of claim 8, wherein the pre-determined resistance value is approximately 20 ohms.

10. An integrated circuit, comprising:
a substrate; and
a plurality of unit cells adjacent the substrate, each unit cell electrically connected to at least one other unit cell;
wherein each unit cell comprises:
a first layer of dielectric material comprising a first via;
a layer of metal adjacent the layer of dielectric material; and
a second layer of dielectric material adjacent the layer of metal, said second layer comprising a second via;
wherein the first via and the second via are electrically connected in series to form a resistor.

11. The circuit of claim 10, wherein at least some of the unit cells are electrically connected in series.

12. The circuit of claim 10, wherein at least some of the unit cells are electrically connected in parallel.

13. The circuit of claim 10, wherein at least a portion of the unit cells are electrically connected in series and at least a portion of the unit cells are electrically connected in parallel.

14. The circuit of claim 13, wherein 32 chains of unit cells are electrically connected in parallel, each chain comprising 80 unit cells electrically connected in series.

15. The circuit of claim 14, wherein the 32 chains of unit cells electrically connected in parallel produce a resistor tolerance of less than ±1%.

16. The circuit of claim 10, further comprising multiple vias electrically connected in series to the first and second vias to implement a pre-determined resistance value.

17. The circuit of claim 16, wherein the pre-determined resistance value is approximately 20 ohms.

18. The circuit of claim 17, wherein the pre-determined resistance value is implemented with a tolerance of ±5%.
